(19) United States
(12) Patent Application Publication
(10) Pub. No.: US 2008/0211512 A1
(43) Pub. Date: Sep. 4, 2008

(54) Test circuit arrangement and testing method for testing of a circuit section

(75) Inventor: Martin Czech, Eschbach (DE)

Correspondence Address: Maginot, Moore & Beck;Chase Tower, Suite 3250, 111 Monument Circle, Indianapolis, IN, 46204, US

(73) Assignee: MICRONAS GmbH, Freiburg (DE)

(21) Appl. No.: 11/807,181

(22) Filed: May 25, 2007

(30) Foreign Application Priority Data
May 26, 2006 (DE) 10 2006 025 031.1

(51) Int. Cl. G01R 31/02

(52) U.S. Cl. 324/537

(57) ABSTRACT

The invention relates to a testing method and to a test circuit arrangement for testing a circuit section of a circuit, having a connection section connected to the circuit section used to conduct a current from or to the circuit section, and having a detector circuit; wherein a first tapping point is arranged on the connection section at a distance from a transition to the circuit section, a second tapping point is arranged at the connection section that is closer to the circuit section than the first tapping point, and wherein the detector circuit samples a voltageor a voltage-equivalent value between the first and the second tapping point for testing of the circuit section.

### FIELD OF THE INVENTION

The invention relates to a test circuit arrangement and to a method of testing of a circuit section.

### BACKGROUND

Many types of testing circuit arrangements are used for testing of unreliable connections, particularly in integrated circuits. Because integrated circuits (IC) increasingly require more current, a constantly increasing number of parallel current paths that are external to the integrated circuit are utilized to distribute the current uniformly to the IC in order to maintain a low resistance and inductance. Such current paths are manufactured partially in a monolithic manufacturing process, which usually results in a higher reliability and quality, but when necessary, partially also with the addition of a process such as for example welding, soldering or pressing of additional macroscopic structural elements such as contact wires, balls, bumps and substrates, that is to say connections which cannot be manufactured monolithically. The latter components lead to problems relating to reliability and quality that are not negligible. In addition, from the viewpoint of the measuring technique, it is almost impossible to identify a failure of one such connection among a great number of parallel connections.

FIG. 4 shows a cutaway portion of a contacting region in an example of an integrated circuit arrangement according to the prior art which is still very common. The figure indicates a segment of a chip or a body of an integrated circuit 50 on whose upper surface is formed a supply network 51, which consists of a plurality of lines mutually intersecting each other. In the edge area of the integrated circuit 50 are connected multiple so-called bond pads 1, which are used to provide a connection to integrated circuit components and strip conductors, or to the supply network 51. In this case, the supply network 51 is connected to several pads 1 using connection sections 2, in the form of strip conductors. Bonding wires forming circuit sections 3 lead from these pads 1 to connection pins 52, which makes it possible, for example, to contact a housing of the integrated circuit 50 with a corresponding base support of a circuit board.

According to this arrangement, supply networks 51 are arranged on a crystal of the integrated circuit 50, wherein for example only the VDD network of the supply voltage VDD is illustrated as the grid structure. Multiple connection pins 52 are assigned input/output functionalities. Other connection pins 52 are used to supply current to the integrated circuit 50, wherein for example only the VDD connection pins are shown. To each of the connection pins 52 is assigned precisely one bonding wire (i.e. contact wire) forming a circuit section 3. These bonding wires represent the weakest point due to the non-monolithic manufacturing technique. A defective connection of each of the bonding wires, and in particular of the VDD bonding wires, can be identified immediately and in a simple manner using a simple contact test performed via the connection pins because each of the bonding wires is assigned precisely to one connection pin 52.

FIG. 5 shows a more recent embodiment of a circuit arrangement based on existing prior art in which the supplying of a current or of a supply voltage VDD is no longer realized with a plurality of connection pins 52, but instead with a common single connection pin 53. The connection pin 53 is deployed with a rail 54 that extends in parallel to the pads 1, wherein the pads 1 that are connected to the corresponding supply network 51 are connected to the rail 54 via a bonding wire forming a circuit section 3. The bonding wires 3 are as a practical manner short-circuited by the rail 54 on one side, and by the supply network 51 of the integrated circuit 50 on the other side, so that the missing of one or more such bonding wires during production cannot be detected.

Similar problems are encountered also with other connection techniques for supply networks 51 of similar integrated circuits 50, which are provided with a macroscopic, non-monolithic parallel design, such as, for example, using substrates that are soldered or glued to a crystal.

In order to solve these problems, various approaches can be used which, however, do not lead to a satisfactory solution. For example, a known circuit arrangement from U.S. Pat. No. 5,521,511 is shown in FIG. 6, in which a current is supposed to be input at such a high level via two connection pins 52a, 52b that significant voltage drops occur at the connection wires 3, such that defective connections can be detected with a voltage meter 67 that detects a voltage V between the contacted pads 1a, 1b. With a trough diode 60 deployed for example between a supply voltage VDD and a base voltage VSS between the connection pins 52a, 52b, a relatively high voltage drop occurs due to the process variations that form of parasitic elements. On the other hand, because the resistance of the bonding or contact wires, which are formed as a circuit section 3, is only about 100 mOhm, the voltage differences to be detected due to the defective bonding wires are drowned out by other voltage variations. Another disadvantage is that effects that are detrimental to product quality are generated because very high currents, on the order of several Amperes, must be applied to obtain a significant drop at 100 mOhm. Moreover, the number of the parallel wires or other connecting elements is not limited to two, since even ten or more such items can be used. This increasingly reduces the probability that a defective connection will be detected.

From DE 198 28 656 A1 it is known to provide an integrated circuit with one contacting position to create a contact with a bonding wire, and equipped with a detector device that is used to detect the condition of the contacting position. The design uses a method for condition detection by measuring a potential on pad itself. DE 689 12 982 T2 describes a method and an arrangement for testing multiple supply connections of an integrated circuit on a printed circuit board. In this case, the voltage drop is measured at conductor paths between parallel pads whereby a higher current is input for this purpose. DE 198 13 503 C1 describes a circuit arrangement designed to prevent erroneous results occurring due to contact defects during the testing of an integrated circuit. Pull-up or pull-down devices deployed between respective integrated pads and the integrated circuit maintain in this case a high or low potential of the pads when a holding current is applied, so that the activation of the circuit part which is connected with the pin is prevented if the appropriate pin of the pad is not contacted. U.S. Pat. No. 5,801,536 describes a testing method for integrated circuit arrangements, wherein a current is conducted from a connection pin through the bonding wires to a pad, from the pad over a resistance to another pad, and from this location through the bonding wires to another connection pin, so that the resistance is measured and used as an evaluation criterion.

### SUMMARY

The object of at least some embodiments of the invention is to propose a test circuit arrangement and a testing method for testing a circuit section of a circuit wherein the input of extremely high currents can be prevented. Preferably, under production conditions, voltage differences can be measured in the range from several hundreds or tens of μV based on total voltages, in particular in the range of 1 V-5 V, including considerable fluctuations of these voltages.

This object is achieved by the test circuit arrangement for testing of a circuit section of a circuit, according to the characteristics of the patent claim 1, or with a testing method having the characteristics according to patent claim 14. Advantageous embodiments are the subject of dependent claims.

A preferred circuit arrangement for testing of a circuit section of a circuit, is equipped with a connecting section connected to the circuit section, which is used to supply a current from or to the circuit section, and with a detector circuit, wherein a first tapping point is arranged at the connecting section at a distance from a junction to a circuit section, a second tapping point is arranged at the connecting section closer to the circuit section than the first tapping point for the circuit section, while the detector circuit samples a voltage or a voltage-equivalent value between the first and the second tapping point for testing of the circuit section.

This makes it possible to test in an advantageous manner any connections when a current flows through such a connection. The current can be in this case a current that is applied separately, or a current which is flowing anyway. Thus, advantageous are particular arrangements in which the applying of a measurement current is not required, as the operating current is sufficient for use in the measurement. This makes it possible to perform measurements in the background, while other circuit parts can be tested in a suitable manner.

Particularly preferred is a test circuit arrangement in which is formed a detector circuit used to detect the electric resistance of the connecting section between the first and the second tapping point.

Particularly preferred is a test circuit arrangement, in which the electric resistance corresponds to at least 10 mOhm. Particularly preferred is a test circuit arrangement, in which the detector circuit is formed to detect a voltage that is less than 100 μV, in particular less than 1 mV, between the first and the second tapping point. Particularly preferred is a circuit, in which the circuit section to be tested is equipped with a bonding wire and the connecting section is equipped with a contact section that is made of metal.

Particularly preferred is a test circuit arrangement, in which the circuit section is formed in order to create a contact to an integrated circuit. Particularly preferred is a test circuit arrangement, in which the circuit section is formed to apply a supply voltage or a reference voltage to a supply network of a circuit arrangement.

Particularly preferred is a test circuit arrangement, in which two or more arrangements comprising connection sections and circuit sections connected in series are connected in parallel to each other, wherein the circuit sections are connected with a common connection point on the side that faces away from the connection sections, and the connecting section are connected with a common connection point on the side that faces away the circuit sections, so that these two or more arrangements which are connected parallel to each other are short-circuited outside of the connection sections and circuit sections, and wherein a first tapping point and a second tapping point of this type is deployed, respectively, on both sides of the connection sections.

Particularly preferred is a test circuit arrangement, in which each of the connection sections can be switched to a base voltage on respective sides that face away using a switch, particularly a transistor. However, transistors are not necessarily required, as they only represent an example of the way in which current can be applied, in particular by means of ESD (ESD: Electro Static Discharge) transistors which are already available.

Even more preferable than the application of transistors is the use of an operating current, for example, which also flows in this manner through the conductor.

Particularly preferred is a test circuit arrangement, in which the detector circuit is formed in order to take into account the resistances on the side of the shorted circuit sections and on the side of the shorted connection sections.

Particularly preferred is a test circuit arrangement equipped with two or more arrangements connected parallel to each other, comprising, respectively, a connection section and a circuit section connected in series, and a first and a second tapping point on the connection sections and a first and a second connection for sampling of the voltage of voltage-equivalent values, wherein the sampling points are provided, respectively, with a switch that is switchable on the first or on the second conduit. Particularly preferred is a test circuit arrangement having transistors as the switching devices.

Particularly preferred is a test circuit arrangement which is equipped with one two-wire bus used to sample the voltage and furnish it to a differential voltage.

Preferred is a method for testing of a circuit section of a circuit, in which an electric voltage or a voltage-equivalent value is measured in order to test the circuit section, wherein the voltage is sampled on a connecting section connected directly in series to the circuit section to be tested.

Particularly preferred is a method, according to which a plurality of arrangements which are connected in parallel to each other, having circuit sections and connection sections, are provided, respectively, with two tapping points on each of the connection sections, so that the tapping points of the various connection sections are multiplexed on the conductors leading to a detector device.

The test circuit arrangement and the testing method are thus based on a measurement concept, according to which it is not necessary to furnish a higher current through the entire section, which could potentially have poorly defined parameters, and according to which is it not necessarily required that the entire voltage be measured externally. A relatively lower current level can be advantageously used in order to induce a small voltage drop locally in one integrated circuit on one connection after another, which can be furnished symmetrically outside, or even evaluated already at circuit integrated in the chip. Although relatively low levels are thus created, these levels are better known and more stabile because the influence of interference is smaller and the signal range between the good and an open connection is in the end greater and thus unambiguous.

The following is a more detailed explanation of embodiment examples of the invention based on the enclosed figures.

### BRIEF DESCRIPTION OF THE DRAWINGS

FIG. 1 a schematic illustration of a circuit section used to enable illustration of a basic principle of a test circuit arrangement according to one preferred embodiment example,

FIG. 2 an exemplary embodiment formed by a test circuit arrangement for testing of a plurality of parallel circuit sections,

FIG. 3 another exemplary test circuit arrangement for testing of a plurality of circuit sections parallel to each other,

FIG. 4 an exemplary circuit arrangement according to the prior art,

FIG. 5 another exemplary circuit arrangement of according to the prior art, and

FIG. 6 yet another circuit arrangement according to prior art.

### DETAILED DESCRIPTION

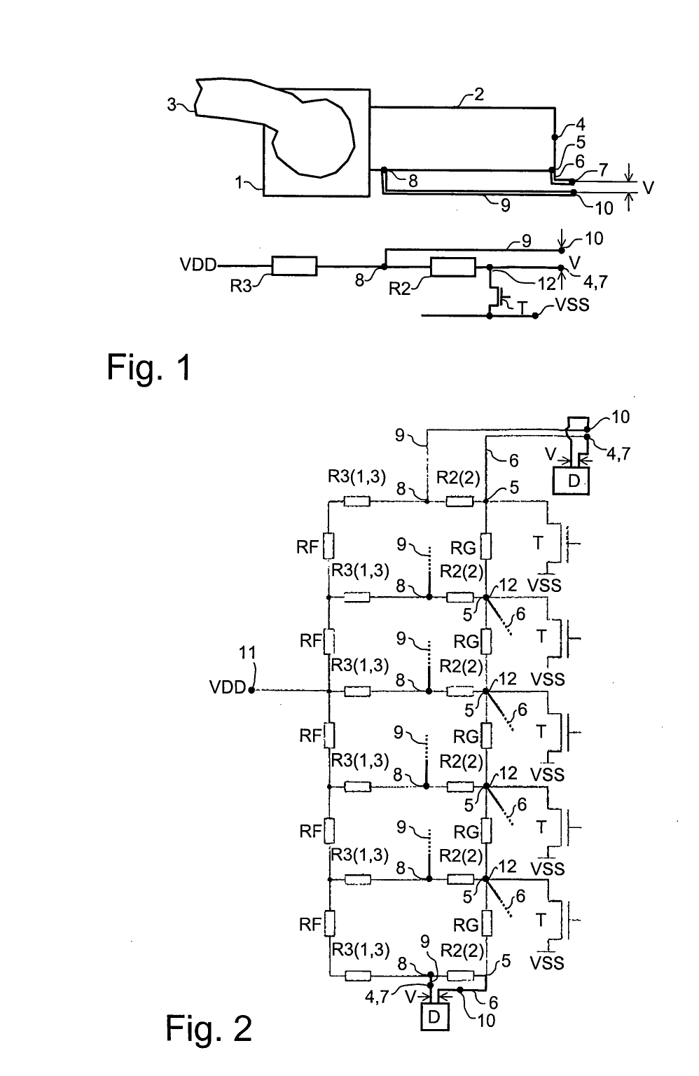

As one can see from the schematic drawing shown in FIG. 1, the figure shows a test circuit arrangement for testing of a circuit section 1, 3 of a circuit according to a simplified embodiment having only a few components. The illustrated circuit sections 1, 3, by way of an example, comprise a pad 1, particularly a bond pad, which is formed from metallic, electrically conductive conductors that are used to supply a connection section 2. The connection section 2 is used to create a contact with conductor paths and/or circuit components relating to other components not shown in the figure. It is particularly preferred that the connection section 2 is formed as an integral constituent part of a supply network, which is generally known and used for a supply of an integrated circuit. As shown in the figure by way of example, a bonding wire 3, which is bonded to the pad 1, is a particularly critical element of the circuit section 1, 3 to be tested. In principle, however, other types of circuit connections can be tested with this type of a test circuit arrangement.

Essential elements of the test circuit arrangement comprise a first tapping point 5 and a second tapping point 8, which are connected to the connection section 2. A tapping point is also known as a sampling point and/or a test point. In this case, the first tapping point 5 is arranged on the connection section 2 at a greater distance than the second tapping point 8 to a junction of the connection section 2 and a circuit section 1, 3 to be tested. When a current of the circuit section 1, 3 flows through the connection section 2, or when a current flow is induced in the corresponding opposite direction, due to the small ohmic resistance of the material of the connection section 2, a small potential difference is created between the first and the second tapping points 5, 8, which can be sampled as a voltage V. For sampling of voltage, a first conduit 6 is provided, which is connected at the first tapping point 5 and which is equipped with a contact point 7 at its other end, as well as a second conduit 9, which is connected to the second tapping point 8 and equipped at its other end with another contact point 10. A voltage V is sampled on both contact points 7, 10 and tested by means of a detector device, not shown in the figure. In the case when the circuit section 1, 3 is interrupted, that is to say when no current flows through the connection section 2, the value of the voltage V equals zero. In the case when an input supply voltage VDD and a continuous current which is based on this voltage is used to supply current to the integrated circuit, the circuit section can thus be closed in reaction to a failure. In particular when several such circuit sections are used which are connected parallel to each other and short-circuited on both sides, the failure of a single such circuit section 1, 3 can be thus detected with reliability.

A corresponding equivalent circuit diagram is shown below the circuit components in FIG. 1. The circuit sections 1, 3 to be tested are represented by a resistor R3, and the connection section 2 connected to it is represented by another resistor R2. The figure also shows the second tapping point 8 located between both resistors R3, R2, which is connected with the second conduit 9 to the contact point 10. On the other side of connection section 2 represented by the resistor R2, a corresponding conductor is connected to a contact point 4, 7, wherein as shown in the equivalent circuit diagram, one connection point 4 of the connection section 2 is combined with the first tapping point 5, with the conduit 6 and with the first contact point 7. In principle, however, a contact point 4 of the second connection point 2 can be also disposed at a distance from the first tapping point 5.

In the equivalent circuit diagram is also shown a transistor T, which is connected between the first contact point 7 and a base voltage VSS.

Both resistors and the optional transistor T are thus connected in series between the supply voltage VDD and the base voltage VSS. Advantageous embodiments using a similar transistor T additionally for the evaluation of the voltage V will now be described based on implementations listed below.

FIG. 1 thus shows a first, particularly preferred exemplary embodiment, which is provided with a bonding wire 3 which contacts a bond pad. The pad 1 is connected through a metal path which is manufacture monolithically with a supply network or with other components of the circuit, which are not shown in the drawing for the sake of simplicity. The electric equivalent circuit diagram shows two resistors R3, R2, which are connected in series and used for testing of the circuit section 1, 3 and of the connection section 2, which is connected to it and is formed as a metal path.

In many examples having an integrated circuit arrangement deployed below the metal path of a connection section 2, a protection transistor, in particular an ESD (Electro Static Discharge) protection transistor or other active elements, are symbolized in the equivalent circuit diagram by the transistors T, which, for example, is formed as a MOS (Metal Oxide Semiconductor) element.

The core of the test circuit arrangement or of the testing method is based on the tapping points 5, 8, which are in particular constructed as thin measurement taps and/or as thin conductors 6, 9, which sample and detect a potential difference in the form of a voltage V on the connection section 2.

According to a customary embodiment provided only by way of an example, calculations can be performed using an electric resistance of 40 mOhm for the connection section 2, so that it can be assumed that a current of only 10 mA flows through the circuit section 1, 3 and the connection section 2 has a potential difference of 400 μV.

If, for example, the bonding wire 3 is missing or if the connection to the pad 1 is damaged, the potential difference or the measured voltage will be equal 0. In reality this value is not exactly 0, since as a result of the value of a residual measurement noise, this function will not be precisely equal to 0, but is considered as a zero for the present purposes. Even worse than the effect of such mostly insignificant measurement noise is the effect of defective voltages, which can be caused, for instance, by leak currents on a two-wire bus and which can be also detected with the preferred arrangement. A very small but very distinct signal is thus provided for this purpose in order to test the circuit section, enabling a determination of the quality of each individual section of such a circuit, in particular of the bond connection.

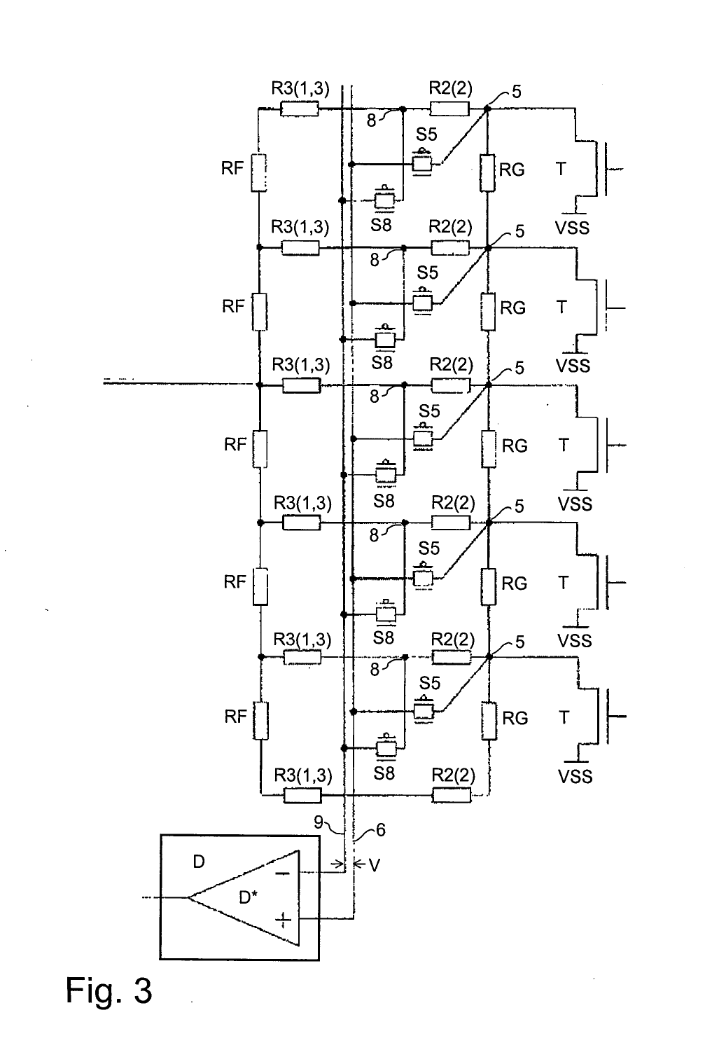

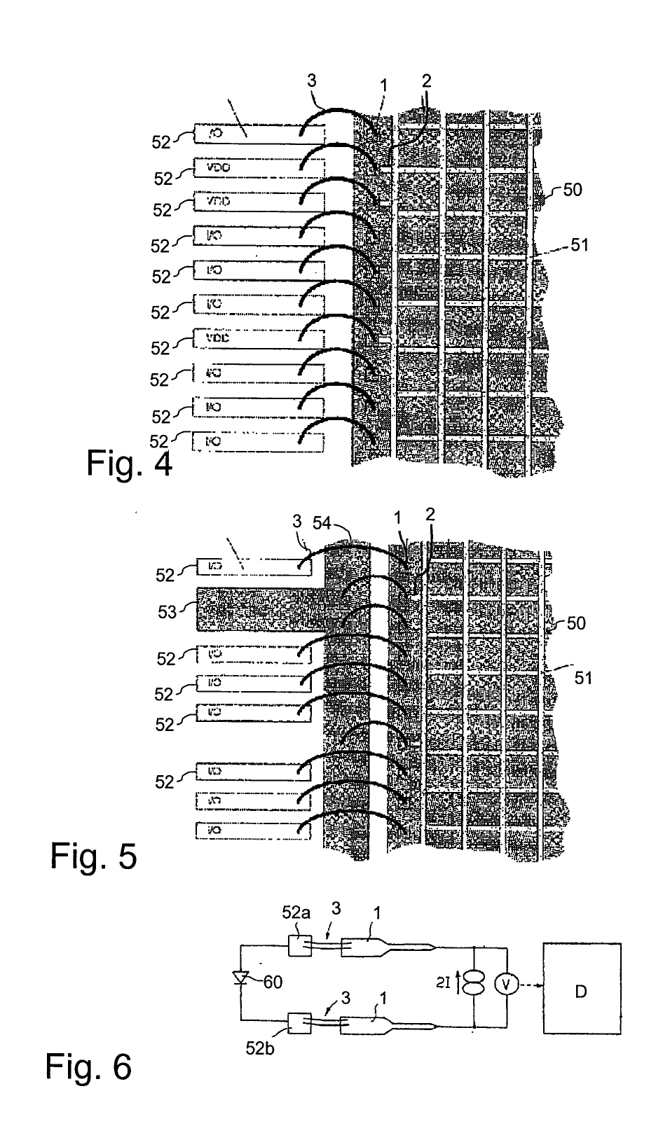

The basic principle, which is illustrated in FIG. 1, can also be advantageously applied to complex circuit arrangements having connections that are deployed in parallel to each other and short-circuited on both sides, as one can see from the illustration shown in FIGS. 2 and 3. In this case, only components and functionalities which are not described in reference to FIG. 1, or those that deviate from the previous description, will be described, while other components and functionalities are based on the embodiment according to FIG. 1. To simplify the explanation, an equivalent circuit diagram that is identical to the equivalent circuit diagram shown in FIG. 1 will be used.

FIG. 2 shows an embodiment that is provided with a single connection point 11 which is used to input a supply voltage VDD. The supply voltage VDD is to be conducted using multiple circuit sections 1, 3, which are parallel to each other, and using connection sections 2, which are connected downstream to a common connection point 4, wherein the connection point 4 is also used as a contact point 7 for sampling of the voltage V. Connection sections 1, 3 and the connection sections 2 are again represented in the equivalent circuit diagram by corresponding resistors R3 or R2.

Finally, this arrangement of the circuit sections 1, 3 and of the connection sections 2 forms in particular a bus bar which can lead to a particular location and which can be provided with tapping points 5, 8 for sampling. In order to sample the voltage, a second tapping point 8 is again equipped with a second conduit 9, which leads to the second contact point 7, 10. Accordingly, voltage V is sampled at the first and at the second contact point 7, 10 and supplied to a detector circuit D shown in the illustration only by way of an example. Such a second tapping point 8 is provided in particular between each of the circuit sections 1, 3 and the connection sections 2. Seen from the viewpoint of these circuits sections 1, 3, a first tapping point 5 is provided also on the other side of the related connections section 2. A respective detector circuit is connected with corresponding conduits 6, 9 and contact points 7, 10, whereby this circuit, shown only from the view point of the lowest arrangement, is suggested for other arrangements.

In particular, such a circuit arrangement of a plurality of circuit sections 1, 3 and respective connection sections 2 which are connected in series can be represented by a corresponding plurality of first and second resistors R3 or R2, connected in series. The first resistors R3, which represent the individual circuit sections 1, 3, are in this case connected through series connections of the distribution resistors RF at the connection contact 11 with the supply voltage VDD. On the other side of the circuit, that is to say, from the viewpoint of the first resistor R3 on the other side of the second resistor R2, the second resistors R2 are connected through grid resistors RG, which represent resistors made of the corresponding grid material connecting the metal path of one of the connection sections 2. In this case, with the exception of both outermost connection sections 2, one connection section or its second resistor R2 will be in each case connected with the grid path, or between two grid resistors RG. These connections are represented by the third contact points 12 in the first equivalent circuit diagram. At the third contact point 12 is preferably again connected a transistor T, which connects these contact points 12 in the connected status with the base voltage VSS.

The third contact points 12 are in the illustrated variation also used as the first tapping points 5.

The supply voltage VDD is thus connected in this embodiment through one distributed distribution resistor RS, through the first resistors R3 represented by the parallel bonding wires connected to each other, and by respective connected connection sections 2, connected in series as metal paths represented as the second resistors R2 in the drawing. The supply grid, which is interconnected to the connection sections 2 or to the second resistors R2, is modeled with the grid resistors RG. In the example shown in FIG. 2, the uppermost and lowermost second resistors R2 are again assigned two wires or conductors 6, 9 at the corresponding tapping points 5, 8 in order to obtain the voltage V over these connection sections 2, or over the second resistor R2 corresponding to these connection sections. To make detection possible, a current must flow through the corresponding second resistor R2 or through the connection section 2. This current can be also a leak current of a supply network that is not shown in the figure, which furnishes the supply voltage VDD, or a current, specifically a MOS current, which is supplied with each of the transistors T per the connection section 2 or per the second resistor R2. A conventional ESD transistor form can be used in an advantageous manner for this purpose for such a transistor T whose current source characteristics can be utilized with advantage.

A detection of a failure of one of the circuit sections 1, 3, or of the resistors R3 shown in the equivalent circuit diagram can thus be determined when the voltage V on the associated tapping points 5, 8 differs from the expected voltage value by a deviating voltage value. Advantageously, the various third contact points 12 can be controlled with corresponding circuits of the transistors T in a manner enabling the detection of which of the individual circuit sections 1, 3 is defective.

FIG. 3 shows a modified embodiment contrasted with the embodiment shown in FIG. 2. Instead of a single measuring tap performed through only one of the connection sections 2 or through only one of the second resistors R2, each of the groups comprising each a circuit section 1, 3 to be monitored and a connection section 2 connected in series, or the corresponding groups shown in the equivalent circuit diagram as comprising a first and a second resistors R3, R2 connected in series, has its own two tapping points 5, 8. In this case, each of these respective two tapping points 5, 8 are respectively connected by a switch S5, S8 associated with these tapping points to a first or a second lead 6 or 9. The switches S5, S8 of each group are in this case connected so that only each respective first and second tapping point 5, 8 of each individual connection section 2, or of the associated resistors R2 shown in the equivalent circuit diagram among the plurality of the parallel connection sections 2, is connected to the first or the second lead 6, 9. A differential voltage amplifier D* is connected to both leads 6, 9 of the embodiment shown in the figure, which is used as a constituent part of the detector circuit.

Such an embodiment form makes it possible in particular to utilize advantages of the MOS technology, wherein for all bonding wires of interest or other non-monolithic connections, the differential voltage is obtained from each respective connection section 2 or from the second resistor R2 and supplied using the MOS switches, which are used as switches S5, S8, through a two-wire bus in the form of the first and second leads 6, 9 to the differential voltage amplifier D* in a multiplexed manner. The differential voltage amplifier D* can in this case be located inside or outside of the integrated circuit. Respective MOS transistor switches S5, S8 can be thus sequentially activated, which will apply differential voltages to the bus, so that the result can be read at the output of the differential amplifier D*.

A large number of bonded, soldered or other connections can thus be tested automatically in this manner during the production of an integrated circuit.

In addition to testing of an integrated circuit during production, a similar circuit can be also tested later during operations, for example in constant intervals, to detect fatigue failures, for example, or to detect defects of the circuit sections occurring due to other influences.

The MOS switches S5, S8 and the thin wires which are used for switching will preferably have a considerable resistance, which is in the kOhm range. Accordingly, a high ohmic differential amplifier D* should be selected in such that practically any current can flow through these effective resistance elements. During the course of a testing process using one such test circuit arrangement, a sufficient time period is preferably provided per measurement, taking into account also a certain ramp-up time period, which is required for every precise analog measurement. The offset of the differential amplifier D* is preferably maintained at a low level with switching techniques that are per se known, for example, with low-offset bipolar introductory stages, or with self-compensating techniques having a compensation stage.

Fault currents, in particular leak currents, can also produce offsets in the leads 6, 9. For the purposes of a better evaluation, a measurement location in the form of a resistor R2 or a section can be built in between two tapping points 5, 8, through which no useful current can flow, whereby the failure of the section between the resistor R3, in particular the resistance of the conduit, can be simulated. It is also possible to associate in this manner also signals, whose value is, for example, on the order of less than 10 μV, even more clearly.

A conversion of such circuit arrangement can be performed in principle with any circuit technique which assumes testing of the reliability of connections.

It is possible to use in this case modules made of discrete components, multichip modules or a single integrated circuit arranged in a housing, as well as mixed forms thereof. Particularly advantageous is the conversion of such a test circuit arrangement for the manufacturing of integrated circuits which have many parallel supply paths, which can be tested with such test circuit arrangements in a simpler manner and with reliability.

Also the use of MOS transistors or of the CMOS technology is possible, as is the use of the NMOS or PMOS technologies. Bipolar transistors can be also used as switches for the impacting of the bus or of the conductors, and they can be also employed for the input of currents.

Only one supply network was used based on the illustrated embodiment examples for the input of a supply voltage VDD. In particular when, for example, PMOS is used as a current source, connections to a VSS network can be also measured, which are located on a base voltage. Several mutually differing networks can be also tested, because when using the switching on of resistors that are connected in series on the two-wire bus or the first and second conductor, it is possible to avoid also ESD problems occurring between the different networks.

In addition to testing of bonding wires and their welding locations used in a circuit section, circuit sections or connections deployed on the other side can be also tested. In principle, testing of any connection technique is possible, whether it is realized with gluing, soldering, welding, contact or bonding wires, substrates, or flip chips, as long as the transmission of the signal is not realized with waves in a wireless manner.

This type of a test circuit arrangement is used primarily for testing of parallel supply paths. Due to the nature of input/output connections, they are usually not connected in parallel and can therefore be measured in a known manner using conventional measurement. Nevertheless, it is also possible to apply the present evaluation capability to such signal paths in which no parallel design is used. This makes it possible in particular to achieve unified testing of all the connected contacts, or connected pins, arranged, for example on a housing of an integrated circuit, because all the circuit sections can be tested with a single testing process or with a single type of a test circuit arrangement. Input/output circuit sections can thus be also included as additional sections to be tested, in particular in a system in which connected connection sections are inserted in both conduits.

1. A circuit arrangement for testing of a circuit section of a circuit, comprising
a connection section connected to the circuit section to conduct a current from or to the circuit section and
a detector circuit configured to obtain a voltage or a voltage equivalent value between a first and a second tapping point in order to test the circuit section, the first tapping point arranged on the connection section at a distance from a transition to the circuit section, and a second tapping point arranged on the connection section that is closer to the circuit section than the first tapping point.

2. The test circuit arrangement according to claim 1, wherein the detector circuit is configured to detect an electrical resistance of the connection section between the first and second tapping point.

3. The test circuit arrangement according to claim 2, wherein the electric resistance corresponds at least to 10 mOhm.

4. The test circuit arrangement according to claim 1, wherein the detector circuit is configured to detect a voltage which is less than 100 μm, in particular less than 1 mV, between the first and the second tapping point.

5. The test circuit arrangement according to claim 1, wherein the circuit section to be tested is includes a bonding wire and the connection section comprises a contact metal surface.

6. The test circuit arrangement according to claim 1, wherein the circuit section is configured to create a contact with an integrated circuit.

7. The test circuit arrangement according to claim 1, wherein the circuit section is configured to provide a supply voltage or reference voltage to a supply network of a circuit arrangement.

8. The test circuit arrangement according to claim 1, wherein two or more arrangements are connected in parallel to each other, each comprising a connection section and a circuit section connected in series, wherein the circuit sections of the two or more arrangements are connected to a common connection point on the sides which are facing away from the connection sections of the two or more arrangements, and wherein the connection sections are connected with a common connection point on the sides which are facing away from the circuit sections, and wherein at least one first tapping point and at least one second tapping point is arranged, respectively, on each side of the connection sections.

9. The test circuit arrangement according to claim 8, wherein each of the connection sections can be controllably connected to a reference voltage via a switch on the side facing away from each circuit sections.

10. The test circuit arrangement according to claim 8, wherein the operation of the detector circuit is dependent on the resistance between tapping points on the side of the circuit sections and on the side of the connection sections.

11. The test circuit arrangement according to claim 1, comprising two or more arrangements connected in parallel to each other, each comprising a connection section and a circuit section connected in series, having, respectively, a first and a second tapping point at the connection sections, and first and second leads for sampling of the voltage, wherein the respective tapping points can be connected by a switch to the first or second leads.

12. The test circuit arrangement according to claim 11, wherein the switches comprise transistors.

13. The test circuit arrangement according to claim 11, wherein the first and second leads comprise a two-wire bus, and further comprising a differential amplifier connected to the two-wire bus.

14. A method for testing a circuit section of a circuit, wherein an electric voltage or a voltage-equivalent value is measured for testing of the circuit section, comprising sampling a voltage in a plurality of connection sections connected directly to the circuit section to be tested.

15. The method according to claim 14, wherein sampling the voltage in the plurality of connection sections further comprises employing a plurality of arrangements connected in parallel to each other, each comprising a circuit section and one of the connection sections, and obtaining voltage across two tapping points on each connection section, wherein the tapping points of the connection sections are multiplexed on two leads.
